(19) United States
(12) Patent Application Publication
(10) Pub. No.: US 2008/0206991 A1
(43) Pub. Date: Aug. 28, 2008

(54) METHODS OF FORMING TRANSISTOR CONTACTS AND VIA OPENINGS

(76) Inventor: Nadia Rahhal-Orabi, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/678,059

(22) Filed: Feb. 22, 2007

(51) Int. Cl. H01L 21/302

(52) U.S. Cl. 438/689

(57) ABSTRACT

A method of forming contacts to a transistor comprises depositing a dielectric layer on a substrate having the transistor, etching a first opening in the dielectric layer that contacts a gate stack of the transistor, depositing a sacrificial material in the first opening, and etching a second and a third opening in the dielectric layer that contact a source and a drain region of the transistor, wherein the second and third openings are etched after the first opening is etched. By etching the opening to the gate stack first, defects such as contact-to-gate shorts are reduced or eliminated.

### BACKGROUND

In the manufacture of integrated circuits, devices such as transistors are formed on a silicon wafer and connected together using multiple metallization layers. The metallization layers include vias and interconnects, as are well known in the art, that function as electrical pathways to interconnect the devices. Vias and interconnects are generally formed by etching openings and trenches into dielectric layers and filling the openings and trenches with a metal.

Transistor contacts are conventionally formed by depositing an interlayer dielectric (ILD) over the transistor, carrying out a first etching process to form trench openings in the ILD over the source and drain regions of the transistor, carrying out a second etching process to form an opening in the ILD over the transistor gate stack, and filling the openings with metal. Unfortunately, as device dimensions decrease, this process for forming electrical contacts can suffer from defects such as contact-to-gate shorts. This is because the trench openings over the source and drain regions are subjected to two wet clean passes, and the wet clean that occurs after the second etching process may degrade these trench openings by removing excess ILD material. This increases the critical dimension of the trench openings and leads to defects.

Furthermore, conventional etching processes used to form via openings suffer from additional drawbacks. For instance, during the etching of a via opening, the photoresist used as a mask for the etching process may degrade during the application of a high powered plasma, leading to bad line edge roughness, extrusions at the edge of the contacts, and pinching off of the contacts. These defects often translate into yield fall out such as contact-to-gate shorts and opens. Accordingly, improved processes for forming transistor contacts and for forming via openings are needed.

### BRIEF DESCRIPTION OF THE DRAWINGS

FIG. 1 is a method of forming contacts to a transistor in accordance with an implementation of the invention.

FIGS. 2A to 2F illustrate structures that are formed when the method of FIG. 1 is carried out.

FIG. 3 is a method of forming a via opening in accordance with an implementation of the invention.

FIGS. 4A to 4F illustrate structures that are formed when the method of FIG. 3 is carried out.

### DETAILED DESCRIPTION

Described herein are systems and methods of forming gate and diffusion contacts for transistors and via contacts for integrated circuits. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

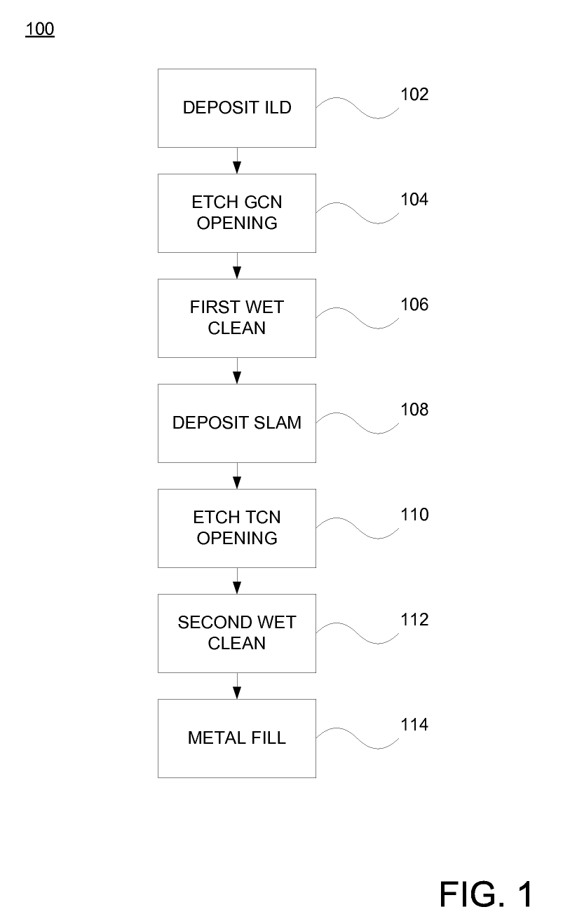

FIG. 1 is a method 100 of forming contacts to a transistor in accordance with an implementation of the invention. Provided with a transistor formed on a semiconductor substrate, the method 100 begins by depositing an interlayer dielectric (ILD) on the substrate over the transistor (process 102 of FIG. 1).

The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group III-V materials. Although a few examples of materials from which the semiconductor substrate may be formed are described here, any material that may serve as a foundation upon which a semiconductor device may be built falls within the spirit and scope of the present invention.

The ILD may be formed using materials known for the applicability in dielectric layers for integrated circuit structures, such as low-k dielectric materials. Such dielectric materials include, but are not limited to, oxides such as silicon dioxide (SiO₂) and carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant.

To form electrical contacts to the transistor, openings must be formed in the ILD that contact the diffusion regions of the transistor (i.e., the source and drain regions) and the gate stack of the transistor. Generally, trench openings are etched in the ILD to form contacts to the diffusion regions while either a trench opening or a via opening is etched in the ILD to form a contact to the gate stack. As used herein, the term “TCN opening” will refer to a trench opening that contacts a diffusion region and the term “GCN opening” will refer to a trench or via opening that contacts the gate stack.

In known prior art processes, TCN openings are etched first, followed by the etching of a GCN opening. As explained above, the TCN openings are subjected to two wet cleans. The first wet clean occurs shortly after the TCN openings are etched in a first etching process. The second wet clean occurs shortly after the GCN opening is etched in a second etching process. The application of two wet cleans to the TCN openings in conventional processes can increase the critical dimension of the TCN openings, causing the TCN openings to accidentally come into electrical contact with the gate stack and cause a contact-to-gate short. Such a short renders the transistor unusable.

Accordingly, contrary to these known methods, implementations of the invention reverse the etching flow and form the GCN opening to the gate stack before the TCN openings are formed. As such, after the ILD deposition, the method 100 continues by etching a GCN opening that contacts a gate stack of the transistor (process 104). Conventional etching processes may be used to form the GCN opening. For instance, a photoresist material may be deposited and patterned to form a mask that defines the GCN opening, and known wet or dry etching processes may then be used to etch the ILD and form the GCN opening that contacts the gate stack. The photoresist mask may then be removed using conventional methods.

A first wet clean process may follow the etching process to clean the GCN opening (process 106). This is the first wet clean that occurs and has no impact on the TCN openings since they have not been formed yet. Conventional wet clean chemistries that are well known in the art and organic solvents may be used to clean the via opening.

A sacrificial layer may be deposited over the ILD to fill the GCN opening (process 108). The sacrificial layer may consist of a sacrificial light-absorbing material (SLAM) or other sacrificial materials known in the art. Some examples of SLAMs that may be used here include, but are not limited to, spin-on-glass (SOG) or SOG-like materials, such as DUO™ spin-on sacrificial materials available from Honeywell Electronic Materials of Tempe, Ariz.

Once the GCN opening to the gate stack is filled, a second etching process is carried out to form TCN openings that contact the diffusion regions, such as the source and drain regions, of the transistor (process 110). Again, conventional etching processes may be used to form the TCN openings to the diffusion regions. For instance, a photoresist material may be deposited and patterned to form as mask that defines the trenches, and known wet or dry etching processes may then be used to etch the ILD and form the TCN openings to the diffusion regions. The mask may then be removed using known methods.

A second wet clean process may now be applied that both removes the sacrificial layer and cleans the TCN openings and the GCN opening (process 112). This wet clean removes the sacrificial layer, such as the SLAM, from the GCN opening after the TCN openings have been formed. This wet clean process is the first wet clean pass for the TCN openings and therefore does not typically create contact-to-gate shorts. And although this wet clean process is the second wet clean pass for the GCN contact, any increase to the critical dimension of the GCN opening has minimal negative impact and does not typically lead to defects. Conventional wet clean chemistries that are well known in the art and organic solvents may be used here.

Finally, conventional processes may be used to fill the trench openings and via opening with one or more metals to form contacts to the transistor (process 114). In some implementations the metal used in all of the openings may be the same metal or the same combination of metals. In other implementations, different metals can be used in the trench openings and the via opening. Metals that may be used here are well known in the art, and include but are not limited to copper, aluminum, tungsten, cobalt, silver, titanium, tantalum, and their alloys.

There are several advantages gained by reversing the conventional process flow and etching the GCN openings first in accordance with implementations of the invention. As stated above, one benefit is the reduction or elimination of contact-to-gate shorts caused by damage to the TCN openings. Another benefit is that due to the small aspect ratio of the GCN opening, the SLAM is relatively easy to remove. In the prior art, because the TCN openings are formed first, the SLAM must be deposited into the TCN openings during the etching of the GCN opening. Because the TCN openings have a large aspect ratio, the SLAM can be difficult to remove.

A final benefit occurs when rework becomes necessary at the GCN opening stage. As is known in the art, rework refers to stripping and re-patterning of the photoresist to modify an opening that fails to meet passing criteria such as critical dimension or registration. In the prior art, if rework was needed after the GCN opening was etched, the TCN openings would be subjected to further wet cleans and further oxide loss. Now, in implementations of the invention, since the TCN openings are formed last, any rework to the GCN opening has no impact on the TCN openings. Furthermore, if rework is needed on the TCN openings, the impact on the GCN opening is minimal because increasing the critical dimension of the GCN opening does not typically lead to defects.

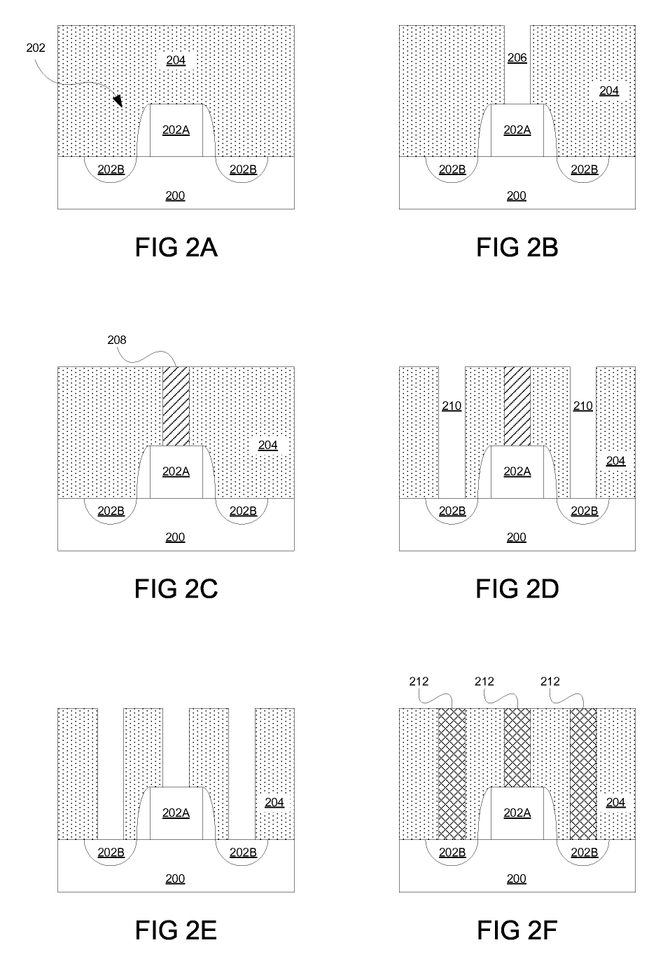

FIGS. 2A to 2F illustrate the structures that are formed when the method 100 of FIG. 1 is carried out. Starting with FIG. 2A, a semiconductor substrate 200 is shown upon which a transistor 202 is formed. The transistor includes a gate stack 202A and diffusion regions 202B. An ILD layer 204 is deposited upon the substrate 200 and the transistor 202.

Moving to FIG. 2B, a first etching process is carried out in which a GCN opening 206 is etched into the ILD layer 204. The GCN opening 206 is etched all the way down to the gate stack 202A. And moving to FIG. 2C, after the GCN opening 206 is cleaned, a SLAM layer 208 is deposited over the ILD layer 204 to fill the GCN opening 206.

Next, as shown in FIG. 2D, a second etching process is carried out to form TCN openings 210 down to the diffusion regions 202B. As mentioned above, the TCN openings 210 tend to be trench openings. Moving to FIG. 2E, the SLAM layer 208 is removed to expose the GCN opening 206. Finally, moving to FIG. 2F, the GCN opening 206 and the TCN openings 210 are filled with a metal 212 to form electrical contacts to the transistor 202.

Another type of defect that can manifest itself in via and trench patterning is related to the line edge roughness of the opening. In conventional processes, the etch has traditionally been done using photoresist material as a mask. Unfortunately, the resist can easily degrade and deform under high power plasma etches. This causes issues such as bad line edge roughness, extrusions at the edge of the openings, and pinching off of the openings. These defects translate into yield fall out.

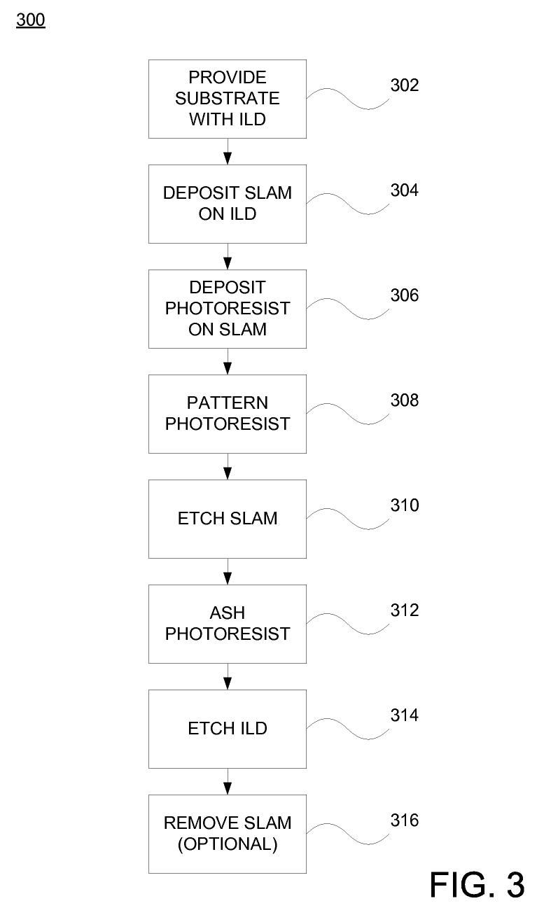

FIG. 3 describes a novel method 300, in accordance with an implementation of the invention, of forming an opening with a reduced likelihood of defects. The method 300 begins with the providing of a semiconductor substrate (302). Examples of semiconductor materials that may be used were provided above. The semiconductor substrate may include a device layer consisting of devices such as transistors, and at least one ILD layer in which the via is being formed. The ILD layer may be atop the device layer or it may be atop one or more metallization layers.

Next, a SLAM layer is deposited over the ILD of the semiconductor substrate (304). Examples of SLAM materials that may be used here include, but are not limited to, SOG or SOG-like materials, such as the DUO™ spin-on sacrificial material described above. The SLAM layer provides multiple functions. The SLAM layer shields the photoresist pattern from underlying topographical variations. The SLAM layer also functions as a hard mask later in the method 300 of FIG. 3. In further implementations, alternate sacrificial materials may be used instead of the SLAM layer. For instance, materials that may be used here include, but are not limited to, organic bottom anti-reflective coating (BARC) materials.

A photoresist layer is deposited over the SLAM layer (306). Photoresist materials that may be used here include, but are not limited to, positive tone photoresists. The photoresist layer is then patterned to form a mask for the via etching process (308). Patterning processes for photoresist materials are well known in the art.

Next, an etching process is carried out to at least partially etch the SLAM layer using a plasma and the photoresist mask (310). The plasma used may be a low powered plasma such as a one kilowatt plasma using SF₆ based chemistries. The etching of the SLAM layer forms a patterned SLAM layer. In various implementations of the invention, the SLAM layer may be partially etched or the SLAM layer may be completely etched. If the plasma etches completely through the SLAM layer, the underlying ILD layer may be partially etched as well.

The underlying ILD layer is not completely etched using the photoresist mask. This is because the high powered plasma used in the etching process can damage the patterned photoresist material. As mentioned above, damage to the photoresist material can lead to defects in the via opening being formed. Therefore, after the etching of the SLAM layer, an in-situ ash process is carried out to ash and remove the patterned photoresist layer (312). The ash process is intended to remove the patterned photoresist layer before the photoresist can cause defects in the via opening.

After the photoresist layer is removed, the plasma etching process continues by now using the patterned SLAM layer as a hard mask to etch a via opening in the ILD (314). Because the SLAM layer is a hard mask, it does not degrade under the high powered plasma. The plasma etching process therefore continues using the SLAM hard mask until the via opening is completely etched in the ILD. If necessary, after the via opening is etched, the SLAM layer may be removed (316). The via opening may also be subjected to a wet clean.

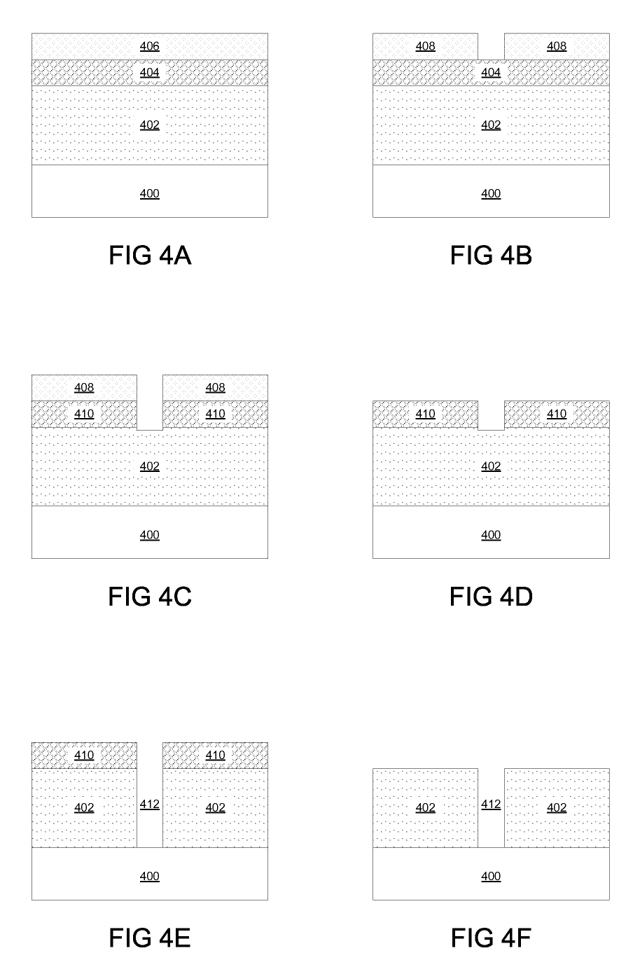

Accordingly, the method 300 results in the formation of a via opening that avoids defects that can occur due to degradation of the photoresist mask. FIGS. 4A to 4F illustrate structures formed with the method 300 is carried out. Starting with FIG. 4A, a semiconductor substrate 400 is shown having a ILD layer 402 deposited upon its surface. A SLAM layer 404 is then deposited on the ILD layer 402, and a photoresist layer 406 is then deposited on the SLAM layer 404.

Next, as shown in FIG. 4B, the photoresist layer 406 is patterned using techniques known in the art. The patterning of the photoresist layer 406 creates a photoresist mask 408.

A low powered plasma etch is then applied to partially etch the structure using the photoresist mask 408, as shown in FIG. 4C. Here, the partial etch patterns the SLAM layer 404, forming a SLAM hard mask 410, and etches a slight portion of the ILD layer 402. In alternate implementations, only a portion of the SLAM layer 404 may be patterned and the ILD layer 402 may not be etched at this stage.

Moving to FIG. 4D, after the partial etch, an ash process is carried out to remove the photoresist mask 408, leaving behind the patterned SLAM hard mask 410. Moving to FIG. 4E, the plasma etch process then continues by using the SLAM hard mask 410 to etch the ILD layer 402 and form a via opening 412. Finally, if desired, the SLAM hard mask 410 may be removed, as shown in FIG. 4F.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
depositing a dielectric layer on a substrate having a transistor;
etching a first opening in the dielectric layer that contacts a gate stack of the transistor;
depositing a sacrificial material in the first opening; and
etching a second and a third opening in the dielectric layer that contact a source and a drain region of the transistor, wherein the second and third openings are etched after the first opening is etched.

2. The method of claim 1, further comprising:
removing the sacrificial material from the first opening; and
depositing one or more metals within the first opening, the second opening, and the third opening.

3. The method of claim 1, wherein the substrate comprises a semiconductor wafer and the dielectric layer comprises a material selected from the group consisting of silicon dioxide, carbon doped oxide, silicon nitride, perfluorocyclobutane, polytetrafluoroethylene, fluorosilicate glass, silsesquioxane, siloxane, and organosilicate glass.

4. The method of claim 1, wherein the performing of the first etching process comprises:
depositing a photoresist material on the dielectric layer;
patterning the photoresist layer to form a photoresist mask that defines the first opening;
etching the dielectric layer using the photoresist mask; and
removing the photoresist mask.

5. The method of claim 1, wherein the performing of the second etching process comprises:
depositing a photoresist material on the dielectric layer;
patterning the photoresist layer to form a photoresist mask that defines the second and third openings;
etching the dielectric layer using the photoresist mask; and
removing the photoresist mask.

6. The method of claim 1, wherein the sacrificial material comprises a SLAM.

7. The method of claim 1, further comprising applying a first wet clean to the substrate after the etching of the first opening.

8. The method of claim 1, further comprising applying a second wet clean to the substrate after the etching of the second and third openings, wherein the second wet clean removes the sacrificial material from the first opening and cleans the first, second, and third openings.

9. The method of claim 8, wherein the second wet clean comprises applying an organic solvent to the substrate.

10. A method comprising:
depositing a sacrificial layer on a dielectric layer;
depositing a photoresist material on the sacrificial layer;
patterning the photoresist material to form a photoresist mask;
etching at least the sacrificial layer using the photoresist mask to form a sacrificial hard mask;
removing the photoresist mask; and
etching the dielectric layer using the sacrificial hard mask to form an opening in the dielectric layer.

11. The method of claim 10, wherein the sacrificial layer comprises a SLAM.

12. The method of claim 10, wherein the photoresist mask is removed using an ashing process.

13. The method of claim 10, wherein the dielectric layer is formed on a semiconductor substrate.

14. The method of claim 10, wherein the sacrificial hard mask is removed after the opening in the dielectric layer is formed.

15. The method of claim 10, wherein the opening comprises a via and trench opening.
